(19) United States
(12) Patent Application Publication
(10) Pub. No.: US 2013/0020554 A1
(43) Pub. Date: Jan. 24, 2013

(54) SEMICONDUCTOR LIGHT EMITTING DEVICE AND LIGHT EMITTING APPARATUS

(71) Applicants: Jong In YANG, Suwon (KR); Tae Hyung Kim, Hwaseong (KR); Young Chul Shin, Seoul (KR); Tae Hyun Lee, Seoul (KR); Sang Yeob Song, Suwon (KR); Tae Hun Kim, Anyang (KR)

(72) Inventors: Jong In YANG, Suwon (KR); Tae Hyung Kim, Hwaseong (KR); Young Chul Shin, Seoul (KR); Tae Hyun Lee, Seoul (KR); Sang Yeob Song, Suwon (KR); Tae Hun Kim, Anyang (KR)

(73) Assignee: Samsung Electronics Co., Ltd.

(21) Appl. No.: 13/553,998

(22) Filed: Jul. 20, 2012

(30) Foreign Application Priority Data
Jul. 22, 2011 (KR) 10-2011-0072814

(51) Int. Cl. H01L 27/15

(52) U.S. Cl. 257/13; 257/E27.12

(57) ABSTRACT

There is provided a semiconductor light emitting device and a light emitting apparatus. The semiconductor light emitting device includes a light emitting diode (LED) part disposed on one region of a light transmissive substrate and including a first conductivity type semiconductor layer, an active layer and a second conductivity type semiconductor layer; and a Zener diode part disposed on the other region of the light transmissive substrate and including a first conductivity type semiconductor layer, an active layer and a second conductivity type semiconductor layer.

### CROSS-REFERENCE TO RELATED APPLICATIONS

This application claims the priority of Korean Patent Application No. 10-2011-0072814 filed on Jul. 22, 2011, in the Korean Intellectual Property Office, the disclosure of which is incorporated herein by reference.

### BACKGROUND OF THE INVENTION

1. Field of the Invention

The present invention relates to a semiconductor light emitting device and a light emitting apparatus.

2. Description of the Related Art

A light emitting diode (LED) is a semiconductor device able to emit light of various colors due to electron-hole recombination occurring at a p-n junction between p-type and n-type semiconductor layers when current is applied thereto. Such an LED is advantageous over a filament-based light emitting device in that it has a long lifespan, low power consumption, superior initial-operation characteristics, and the like. These factors have continually boosted the demand for LEDs. Notably of late, a great deal of attention has been drawn to group III nitride semiconductors that can emit light in a blue/short wavelength region.

Since the development of nitride semiconductor devices, technical advances to broadening the range of applications thereof have been made. Thus, many studies are being conducted into determining how to utilize nitride semiconductor devices in general lighting apparatuses and electrical lighting sources. According to the related art, nitride light emitting devices have been used as components employed in low-current, low output mobile products. However, of late, the range of applications of nitride light emitting devices has been broadened to encompass the field of high-current, high-output products.

Meanwhile, in a case in which a light emitting apparatus is fabricated using an LED, a Zener diode is used to protect the LED from electrostatic discharge (ESD) voltage. In general, such a Zener diode is mounted together with the LED in a package. However, a process of mounting the Zener diode in the package is additionally required. Further, the Zener diode itself and an additional wire for applying an electrical signal to the Zener diode may cause a reduction in luminous efficiency. In this technical field, an attempt to integrate the LED with the Zener diode is being made.

### SUMMARY OF THE INVENTION

An aspect of the present invention provides a semiconductor light emitting device integrated with a Zener diode, thereby improving convenience and reliability in a package process.

An aspect of the present invention also provides a semiconductor light emitting device improving the operational reliability of a Zener diode being integrated therewith and the heat dissipation when mounted in a light emitting apparatus.

An aspect of the present invention also provides a light emitting apparatus including the above-described semiconductor light emitting device.

According to an aspect of the present invention, there is provided a semiconductor light emitting device including: a light emitting diode (LED) part disposed on one region of a light transmissive substrate and including a first conductivity type semiconductor layer, an active layer and a second conductivity type semiconductor layer; a Zener diode part disposed on the other region of the light transmissive substrate and including a first conductivity type semiconductor layer, an active layer and a second conductivity type semiconductor layer; a first connection electrode connecting the first conductivity type semiconductor layer of the LED part to the second conductivity type semiconductor layer of the Zener diode part; a second connection electrode connecting the second conductivity type semiconductor layer of the LED part to the first conductivity type semiconductor layer of the Zener diode part; an insulating part covering the first and second connection electrodes and having an open region allowing at least a portion of the first and second connection electrodes to be exposed; and first and second pad electrodes formed on the first and second connection electrodes exposed through the open region and connected to the first and second connection electrodes, respectively.

The insulating part may allow an upper region of the LED part to be unexposed outwardly.

The insulating part may allow an upper region of the Zener diode part to be unexposed outwardly.

The first and second pad electrodes may not be provided in a region of the Zener diode part.

The first and second pad electrodes may occupy 80% to 95% of an area of an upper surface of the semiconductor light emitting device.

The LED part may further include at least one first electrode provided on one surface of the first conductivity type semiconductor layer, and the first connection electrode maybe connected to the at least one first electrode.

The at least one first electrode may penetrate the active layer and the second conductivity type semiconductor layer of the LED part, and the at least one first electrode may be enclosed by the insulating part and electrically separated from the active layer and the second conductivity type semiconductor layer.

The LED part may further include a second electrode provided on one surface of the second conductivity type semiconductor layer, and the second connection electrode may be connected to the second electrode.

The second electrode maybe formed of a light reflective material.

The second electrode may be disposed to enclose the at least one first electrode.

The first and second electrodes may have upper surfaces disposed on the same level.

The first and second electrodes maybe disposed in the same direction.

The first and second pad electrodes may be formed of a eutectic metal.

According to another aspect of the present invention, there is provided a light emitting apparatus including: a mounting substrate; and a semiconductor light emitting device mounted on the mounting substrate and emitting light when an electrical signal is applied thereto, wherein the semiconductor light emitting device includes: a light emitting diode (LED) part disposed on one region of a light transmissive substrate and including a first conductivity type semiconductor layer, an active layer and a second conductivity type semiconductor layer; a Zener diode part disposed on the other region of the light transmissive substrate and including a first conductivity type semiconductor layer, an active layer and a second conductivity type semiconductor layer; a first connection electrode connecting the first conductivity type semiconductor layer of the LED part to the second conductivity type semiconductor layer of the Zener diode part; a second connection electrode connecting the second conductivity type semiconductor layer of the LED part to the first conductivity type semiconductor layer of the Zener diode part; an insulating part covering the first and second connection electrodes and having an open region allowing at least a portion of the first and second connection electrodes to be exposed; and first and second pad electrodes formed on the first and second connection electrodes exposed through the open region and connected to the first and second connection electrodes, respectively.

The mounting substrate may be a circuit board.

The mounting substrate may be a lead frame.

The first and second pad electrodes may be disposed toward the mounting substrate when the semiconductor light emitting device is mounted on the mounting substrate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic plan view illustrating a semiconductor light emitting device according to an embodiment of the present invention;

FIG. 2 is a schematic cross-sectional view, taken along line A-A′ of FIG. 1;

FIG. 3 is a schematic cross-sectional view, taken along line B-B′ of FIG. 1;

FIGS. 4 through 14 are schematic views illustrating a method of manufacturing a semiconductor light emitting device according to an embodiment of the present invention; and

FIG. 15 is a schematic cross-sectional view illustrating a light emitting apparatus according to another embodiment of the present invention.

### DETAILED DESCRIPTION OF THE EMBODIMENTS

Embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements .

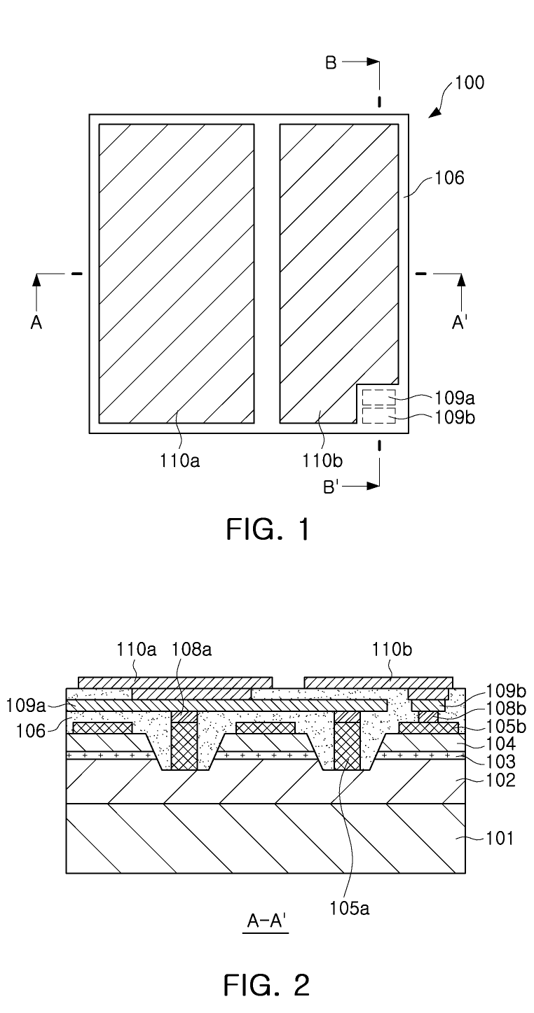

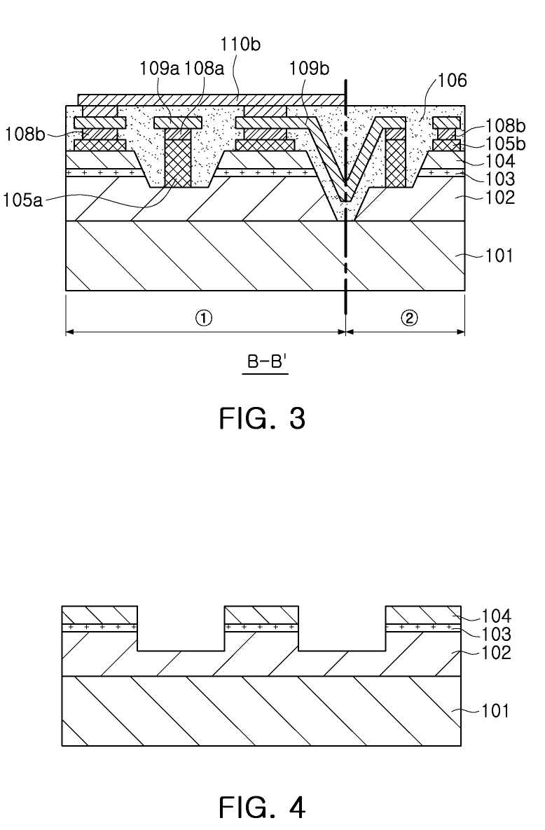

FIG. 1 is a schematic plan view illustrating a semiconductor light emitting device according to an embodiment of the present invention. FIG. 2 is a schematic cross-sectional view, taken along line A-A′ of FIG. 1, and FIG. 3 is a schematic cross-sectional view, taken along line B-B′ of FIG. 1. With reference to FIGS. 1 through 3, a semiconductor light emitting device 100 has a structure in which a light emitting diode (LED) part \textcircled{1} is disposed in one region of a light transmissive substrate 101 and a Zener diode part \textcircled{2} is disposed in the other region thereof. That is, the semiconductor light emitting device 100 has the Zener diode part \textcircled{2} integrated thereinto, and accordingly, when applied to a package or the like, it is not necessary to mount a Zener diode. For this reason, processing convenience may be achieved, and an electrical short in wire bonding for Zener diode connection may not occur. In addition, the Zener diode is included in the semiconductor light emitting device 100, so that the degree of integration in the package or the like may be enhanced.

With reference to FIGS. 2 and 3, the LED part \textcircled{1} includes a first conductivity type semiconductor layer 102, an active layer 103, and a second conductivity type semiconductor layer 104. A first electrode 105a is formed on a surface of the first conductivity type semiconductor layer 102, and a second electrode 105b is formed on a surface of the second conductivity type semiconductor layer 104. Further, the Zener diode part \textcircled{2} includes a first conductivity type semiconductor layer 102, an active layer 103, and a second conductivity type semiconductor layer 104. A first electrode 105a is formed on a surface of the first conductivity type semiconductor layer 102, and a second electrode 105b is formed on a surface of the second conductivity type semiconductor layer 104. In this case, in order to form the first electrode 105a, portions of the first conductivity type semiconductor layer 102, the active layer 103, and the second conductivity type semiconductor layer 104 may be removed. Accordingly, lateral surfaces of the LED part \textcircled{1} and the Zener diode part \textcircled{2} may be inclined. However, as shown in FIG. 4, the lateral surfaces may not be inclined according to a method of removing the portions of the first conductivity type semiconductor layer 102, the active layer 103, and the second conductivity type semiconductor layer 104.

A first connection electrode 109a is formed to electrically connect the first conductivity type semiconductor layer 102 of the LED part \textcircled{1} to the second conductivity type semiconductor layer 104 of the Zener diode part \textcircled{2}, and a second connection electrode 109b is formed to electrically connect the second conductivity type semiconductor layer 104 of the LED part \textcircled{1} to the first conductivity type semiconductor layer 102 of the Zener diode part \textcircled{2}. Also, in order to prevent an electrical short, an insulating part 106 may be formed in upper regions of the first and second connection electrodes 109a and 109b and peripheral regions of the first and second electrodes 105a and 105b. In this case, the insulating part 106 may have open regions through which at least portions of the first and second connection electrodes 109a and 109b are exposed. First and second pad electrodes 110a and 110b may be respectively connected to the first and second connection electrodes 109a and 109b through the open regions, such that external electrical signals may be applied thereto. Hereinafter, detailed descriptions of individual elements will be provided.

The light transmissive substrate 101 may be provided as a semiconductor growth substrate, and may utilize a substrate formed of a semiconductor material having insulation or conductivity properties, such as sapphire, SiC, MgAl₂O₄, MgO, LiAlO₂, LiGaO₂, GaN or the like. The light transmissive substrate 101 may allow at least a portion of light emitted from the active layer 103 to be transmitted therethrough. In this case, sapphire having electrical insulation properties may most preferably be used. Sapphire is a crystal having Hexa-Rhombo R3C symmetry and has a lattice constant of 13.001 Å along a C-axis and a lattice constant of 4.758 Å along an A-axis. Orientation planes of the sapphire include a C (0001) plane, anA (1120) plane, an R (1102) plane, and the like. Particularly, the C plane is mainly used as a substrate for nitride growth because it relatively facilitates the growth of a nitride film and is stable at high temperatures. Meanwhile, although not shown, a plurality of uneven structures maybe formed on an upper surface of the light transmissive substrate 101, namely, a semiconductor growth surface, such that they increase crystallinity and light emission efficiency.

The first and second conductivity type semiconductor layers 102 and 104 provided in both the LED part \textcircled{1} and the Zener diode part \textcircled{2} maybe semiconductor layers doped with n-type and p-type impurities, respectively; however, the invention is not limited thereto. On the contrary, the first and second conductivity type semiconductor layers 102 and 104 may be p-type and n-type semiconductor layers, respectively. The first and second conductivity type semiconductor layers 102 and 104 may be formed of a nitride semiconductor. For example, a material having a compositional formula of AlₓIn_{y}Ga_{1-x-y}N (0≦x≦1, 0≦y≦1, 0≦x+y≦1) may be used therefor. Besides, an AlGaInP semiconductor or an AlGaAs semiconductor may also be used. The active layer 103, disposed between the first and second conductivity type semiconductor layers 102 and 104, may have a multi-quantum well (MQW) structure in which quantum well and quantum barrier layers are alternately stacked, and here, in the case of the nitride semiconductor, a GaN/InGaN structure may be used. The active layer 103 of the Zener diode part \textcircled{2} is not intended to emit light, so it may have a different structure from that of the active layer 103 of the LED part \textcircled{1}. Meanwhile, the first and second conductivity type semiconductor layers 102 and 104 and the active layer 103 forming a light emitting structure may be grown by a semiconductor-layer growth process known in the art, such as Metal Organic Chemical Vapor Deposition (MOCVD), Hydride Vapor Phase Epitaxy (HVPE), Molecular Beam Epitaxy (MBE), or the like.

The first and second electrodes 105a and 105b provided in both the LED part \textcircled{1} and the Zener diode part \textcircled{2} maybe formed of a conductive material that exhibits electrical ohmic-characteristics with the first and second conductivity type semiconductor layers 102 and 104, respectively, and may have a single layer structure or a multilayer structure. For example, the first and second electrodes 105a and 105b may be formed of at least one of Ag, Al, Ni, Cr, a transparent conductive oxide (TCO) and the like using a deposition method, a sputtering method or the like. The first and second electrodes 105a and 105b may be disposed in the same direction, and as will be described below, maybe mounted in a flip chip configuration using a lead frame or the like. Also, the first and second electrodes 105a and 105b may be formed using the same mask pattern simultaneously or sequentially. In this case, as shown in FIGS. 2 and 3, upper surfaces of the first and second electrodes 105a and 105b may have the same level.

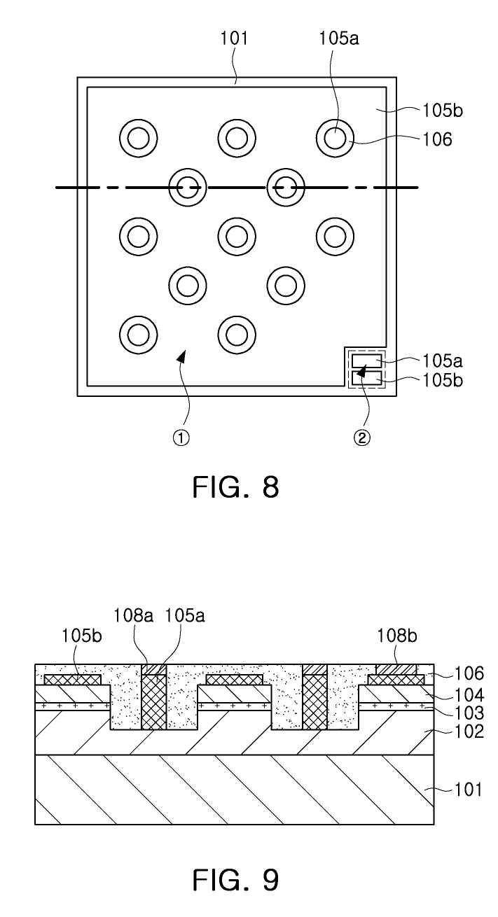

Meanwhile, as will be described with reference to FIG. 8, the first electrode 105a of the LED part may be provided in plural. In this case, the plurality of first electrodes 105a may penetrate the active layer 103 and the second conductivity type semiconductor layer 104, and may be arranged in rows and columns to thereby allow for uniform current flow. In this case, the first electrodes 105a maybe enclosed by the insulating part 106 and be electrically separated from the active layer 103 and the second conductivity type semiconductor layer 104. Further, as shown in FIG. 8, the first electrodes 105a may also be enclosed by the second electrode 105b. The second electrode 105b may exhibit electrical ohmic-characteristics with the second conductivity type semiconductor layer 104, and may be formed of a light reflective material such that light emitted from the active layer 103 is introduced toward the light transmissive substrate 101 when the semiconductor light emitting device 100 is mounted in a flip-chip structure. However, the second electrode 105b is not necessarily formed of a light reflective material. The second electrode 105b may be formed of a transparent conductive oxide or the like.

The insulating part 106 may be formed of a material having electrical insulation properties. For example, a light transmissive material such as a silicon oxide, a silicon nitride or the like may be used therefor. Further, a light reflective filler may be dispersed in the light transmissive material, thereby forming a light reflective structure.

The first and second connection electrodes 109a and 109b are provided to electrically connect the LED part \textcircled{1} and the Zener diode part \textcircled{2}. The first and second connection electrodes 109a and 109b may be connected to the first and second electrodes 105 and 105b of the LED part \textcircled{1}, respectively, while they may be connected to the second and first electrodes 105b and 105a of the Zener diode part \textcircled{2}, respectively. In this case, the first and second connection electrodes 109a and 109b and the first and second electrodes 105a and 105b may directly contact each other, or may have the first and second conductive layers 108a and 108b interposed therebetween. The first and second conductive layers 108a and 108b may not be essential in the present embodiment and may be excluded therefrom. However, the first and second conductive layers 108a and 108b formed of an appropriate conductive material may further reduce electrical resistance between the first and second connection electrodes 109a and 109b and the first and second electrodes 105a and 105b, and may allow them to be spaced apart from each other to thereby prevent an unintended electrical short therebetween.

The first and second connection electrodes 109a and 109b maybe formed of the same material as that of the first and second electrodes 105a and 105b, but may be formed of different materials therefrom according to a designer's intention. In a case in which the second electrode 105b is formed of a light transmissive material, the first and second connection electrodes 109a and 109b may be formed of a light reflective material. Meanwhile, FIG. 3 shows that the second connection electrode 109b may be bent according to the shapes of the LED part \textcircled{1} and the Zener diode part \textcircled{2} in a region between the LED part \textcircled{1} and the Zener diode part \textcircled{2}. However, the structure thereof may not be limited thereto. Specifically, the insulating part 106 may be planarized in the region between the LED part \textcircled{1} and the Zener diode part \textcircled{2} before the forming of the second connection electrode 109b, such that the second connection electrode 109b may be formed to be planarized, without having the bent portion. In this case, electrical characteristics and reliability may be improved.

The first and second pad electrodes 110a and 110b may be connected to the first and second connection electrodes 109a and 109b, and may function as external terminals of the semiconductor light emitting device 100. The first and second pad electrodes 110a and 110b may be formed as a single layer or two or more layers. As shown in FIG. 2, in the case in which the first and second pad electrodes 110a and 110b are formed as two layers, a lower layer of the two layers, i.e., the layer formed in the open region of the insulating part 106 and contacting the connection electrode, and an upper layer thereof may be formed of the same material or different materials. In the present embodiment, the first and second pad electrodes 110a and 110b may be formed of a eutectic metal such as AuSn or the like. When mounted in a package or the like, the first and second pad electrodes 110a and 110b may be bonded by eutectic bonding, so there is no need to use a solder bump generally required in a flip chip bonding process. As compared with a case of using the solder bump, the mounting process using the eutectic metal may allow for superior heat dissipation. In this case, in order to obtain superior heat dissipation, the first and second pad electrodes 110a and 110b may be formed to occupy a relatively wide area. Specifically, the area occupied by the first and second pad electrodes 110a and 110b may be 80% to 95% with respect to an overall area of an upper surface of the semiconductor light emitting device.

Meanwhile, according to the present embodiment, as shown in FIGS. 1 and 3, an upper region of the Zener diode part \textcircled{2} may not be exposed outwardly and that of the LED part \textcircled{1} may not be exposed outwardly, either, due to the insulating part 106. That is, the other elements in the upper region of the semiconductor light emitting device 100, except for the first and second pad electrodes 110a and 110b and the insulating part 106, may not be exposed outwardly, such that a main functional region of the semiconductor light emitting device 100 may be protected. Further, as shown in FIG. 1, the first and second pad electrodes 110a and 110b may not be formed in a region of the semiconductor light emitting device 100 corresponding to the Zener diode part \textcircled{2}. Ina case in which the first and second pad electrodes 110a and 110b may be formed above the Zener diode part \textcircled{2} and the first and second pad electrodes 110a and 110b and oppositely polarized conductors have the insulating part 106 interposed therebetween, the conductor may function as a capacitor such that the operations of the Zener diode part \textcircled{2} may be affected.

In the case of the semiconductor light emitting device 100 having the above-described structure, when the Zener diode integrated into the semiconductor light emitting device 100 is applied to the package or the like, processing convenience and reliability may be improved. Further, the pad electrodes able to be adopted in the eutectic bonding may be used to thereby improve heat dissipation. In addition, the regions of the semiconductor light emitting device functioning as the Zener diode part and the LED part may not be exposed outwardly, whereby the semiconductor light emitting device maybe operated stably. The above-described structure of the semiconductor light emitting device may be more easily understood through a detailed description of a method of manufacturing the same.

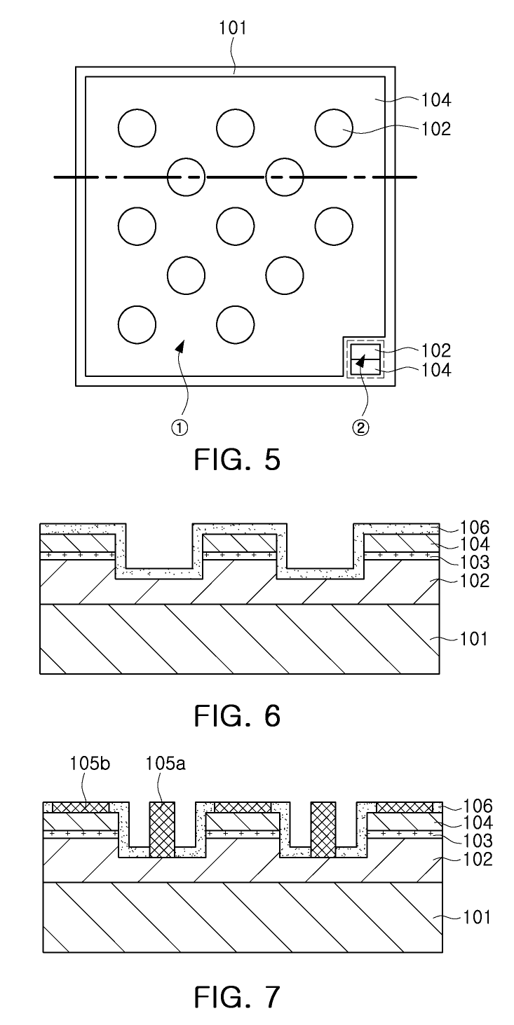

FIGS. 4 through 14 are schematic views illustrating a method of manufacturing a semiconductor light emitting device according to an embodiment of the present invention. In the method of manufacturing a semiconductor light emitting device according to the present embodiment, a semiconductor stack may first be formed, as shown in FIG. 4 (a cross-sectional view) and FIG. 5 (a plan view), by growing the first conductivity type semiconductor layer 102, the active layer 103 and the second conductivity type semiconductor layer 104 on the light transmissive substrate 101 using MOCVD, HVPE or the like. This semiconductor stack may include all regions functioning as the LED part and the Zener diode part. After the forming of the semiconductor stack, the portions of the first conductivity type semiconductor layer 102, the active layer 103 and the second conductivity type semiconductor layer 104 are removed to thereby expose the first conductivity type semiconductor layer 102. This is intended to form the first electrode and divide the semiconductor stack into the LED part and the Zener diode part. In this embodiment, the lateral surfaces of the semiconductor stack may be etched so as not to be inclined.

Next, as shown in FIG. 6, the insulating part 106 may be formed on the second conductivity type semiconductor layer 104. Then, as shown in FIG. 7 (a cross-sectional view) and FIG. 8 (a plan view), portions of the insulating part 106 maybe etched to thereby expose the first and second conductivity type semiconductor layers 102 and 104, and the first and second electrodes 105a and 105b may be formed on the exposed portions, respectively. The first and second electrodes 105a and 105b may be formed on both the LED part \textcircled{1} and the Zener diode part \textcircled{2}. The first and second electrodes 105a and 105b may be formed by a deposition process, a sputtering process, a plating process or the like, known in the art. In this case, the first and second electrodes 105a and 105b may be formed of the same material for an efficient manufacturing process. As shown in FIG. 7, upper surfaces thereof may be on the same level. In addition, as described above, the first electrodes 105a may penetrate the active layer 103 and the second conductivity type semiconductor layer 104 to provide uniform current flow. As shown in FIG. 8, the second electrode 105b maybe integrally formed to enclose the first electrodes 105a.

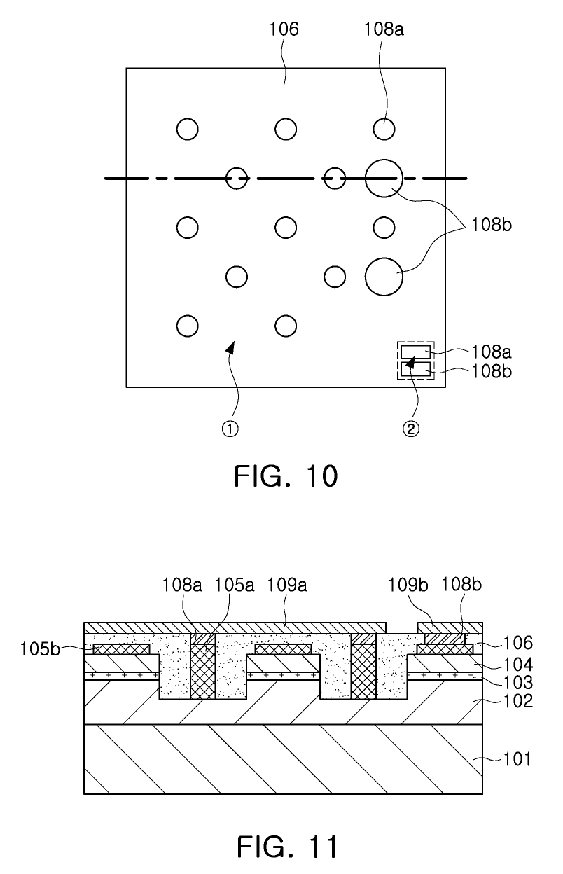

Next, as shown in FIG. 9 (a cross-sectional view) and FIG. 10 (a plan view), the insulating part 106 may be formed to cover the first and second electrodes 105a and 105b and have the open regions through which the first and second conductive layers 108a and 108b are formed in both the LED part \textcircled{1} and the Zener diode part \textcircled{2}. In this case, the first and second conductive layers 108a and 108b may be formed of the same material as that of the first and second electrodes 105a and 105b or of different materials therefrom. However, the forming of the first and second conductive layers 108a and 108b may not be performed, and the connection electrodes may directly be formed on the first and second electrodes 105a and 105b.

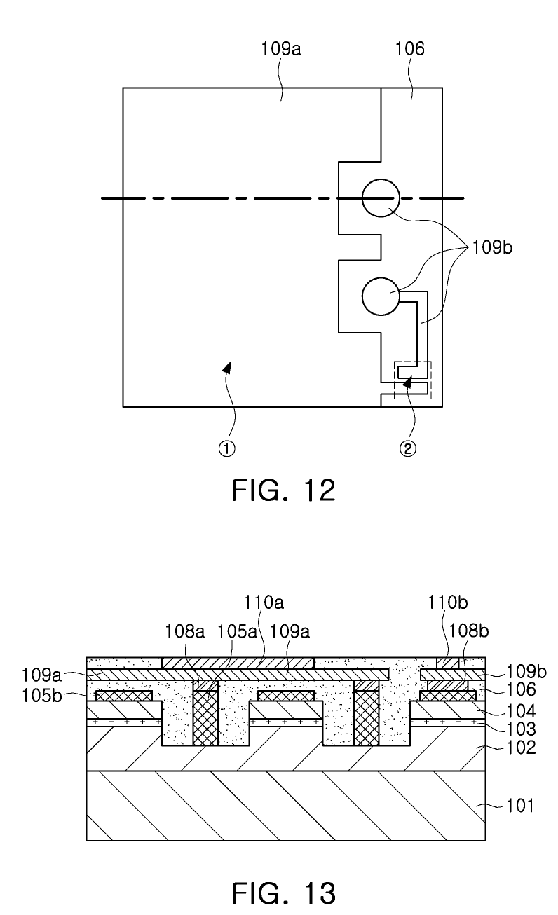

Then, as shown in FIG. 11 (a cross-sectional view) and FIG. 12 (a plan view), the first and second connection electrodes 109a and 109b may be formed. The first and second connection electrodes 109a and 109b may electrically connect the LED part \textcircled{1} and the Zener diode part \textcircled{2} that are separated from each other. In particular, the first connection electrode 109a may be provided to connect the plurality of first electrodes 105a included in the LED part \textcircled{1}. To enable this, the first and second connection electrodes 109a and 109b may be shaped as shown in FIG. 12. However, the first and second connection electrodes 109a and 109b may have various shapes allowing for the same function. Meanwhile, the first and second connection electrodes 109a and 109b may be appropriately designed and be formed by depositing a high reflective material.

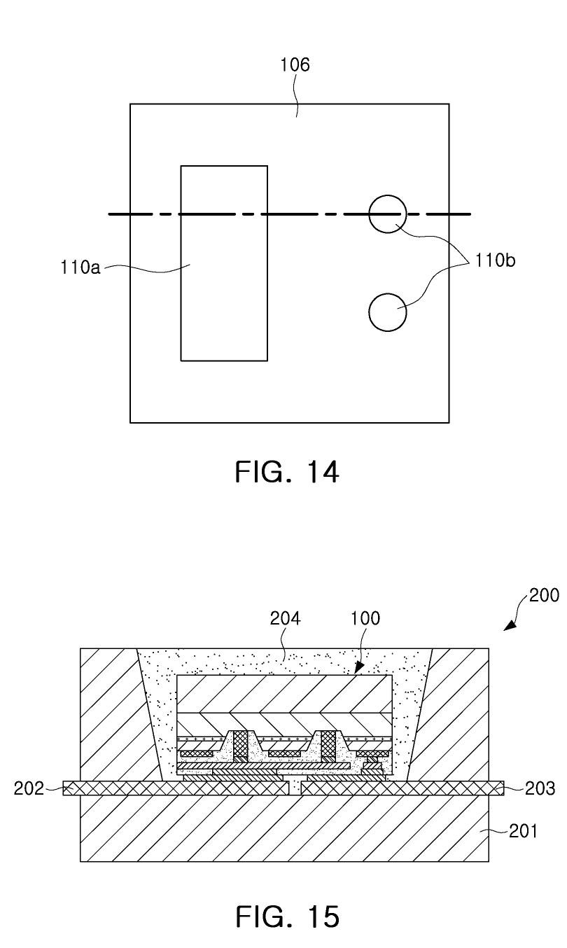

Then, as shown in FIG. 13 (a cross-sectional view) and FIG. 14 (a plan view), the insulating part 106 may be additionally formed, and the first and second pad electrodes 110a and 110b may be formed to be connected to the first and second connection electrodes 109a and 109b, respectively. As described above, the first and second pad electrodes 110a and 110b maybe formed of a eutectic metal such as AuSn or the like. As shown in FIG. 14, the first and second pad electrodes 110a and 110b may be formed as a single layer. Further, a single additional layer may be formed thereon to thereby obtain the structure of FIGS. 1 through 3. In this case, the first and second pad electrodes 110a and 110b disposed in an outermost position may occupy 80% to 95% of the area of the upper surface of the semiconductor light emitting device in order that they are able to serve to provide sufficient heat dissipation.

The semiconductor light emitting device having the above-described structure may be mounted on a mounting substrate or the like, thereby being used as a light emitting apparatus such as a backlight unit used for a display device, an indoor/outdoor illumination device, a headlight, or the like.

FIG. 15 is a schematic cross-sectional view illustrating a light emitting apparatus according to another embodiment of the present invention. A light emitting apparatus 200 according to this embodiment may have a package structure, and include a package body 201, lead frames 202 and 203, and the semiconductor light emitting device 100. Further, a sealing resin 204 may be formed to protect the semiconductor light emitting device 100. In this case, the semiconductor light emitting device 100 may have the structure of FIGS. 1 through 3. In a case in which the semiconductor light emitting device 100 is disposed in a flip-chip structure, the first and second pad electrodes may be disposed towards the lead frames 202 and 203. In a case in which the semiconductor light emitting device 100 is disposed on the mounting substrate, the first and second pad electrodes may be disposed towards the mounting substrate. In this case, the first and second pad electrodes may be bonded to the lead frames 202 and 203 by eutectic bonding. Accordingly, this mounting process may allow for superior heat dissipation, as compared with a case of using a solder bump. In addition, since the semiconductor light emitting device 100 is integrally provided with the Zener diode, there is no need to mount a Zener diode in the light emitting apparatus 200. Therefore, wire bonding is not required in the light emitting apparatus 200 according to this embodiment, and thus, deterioration of reliability due to defects in wiring process may be avoided.

Meanwhile, the package structure of the light emitting apparatus 200 may be modified. For example, lower surfaces of the lead frames 202 and 203 may be exposed outwardly without the package body 201. In this case, the sealing resin 204 may serve to maintain the shapes of the lead frames 202 and 203 while protecting the semiconductor light emitting device 100. Alternatively, the light emitting apparatus may have the semiconductor light emitting device 100 mounted on the mounting substrate such as a PCB, an MCPCB, an FPCB, an MPCB or the like, rather than having the package structure.

As set forth above, according to embodiments of the invention, a semiconductor light emitting device has a Zener diode integrated thereinto, thereby improving convenience and reliability in a package process.

Further, the operational reliability of the Zener diode integrated with the semiconductor light emitting device may be improved, and when mounted in a light emitting apparatus, heat dissipation may be enhanced.

A light emitting apparatus including the above semiconductor light emitting device may be obtained.

While the present invention has been shown and described in connection with the embodiments, it will be apparent to those skilled in the art that modifications and variations can be made without departing from the spirit and scope of the invention as defined by the appended claims.

What is claimed is:

1. A semiconductor light emitting device comprising:
a light emitting diode (LED) part disposed on one region of a light transmissive substrate and including a first conductivity type semiconductor layer, an active layer and a second conductivity type semiconductor layer;
a Zener diode part disposed on the other region of the light transmissive substrate and including a first conductivity type semiconductor layer, an active layer and a second conductivity type semiconductor layer;
a first connection electrode connecting the first conductivity type semiconductor layer of the LED part to the second conductivity type semiconductor layer of the Zener diode part;
a second connection electrode connecting the second conductivity type semiconductor layer of the LED part to the first conductivity type semiconductor layer of the Zener diode part;
an insulating part covering the first and second connection electrodes and having an open region allowing at least a portion of the first and second connection electrodes to be exposed; and
first and second pad electrodes formed on the first and second connection electrodes exposed through the open region and connected to the first and second connection electrodes, respectively.

2. The semiconductor light emitting device of claim 1, wherein the insulating part allows an upper region of the LED part to be unexposed outwardly.

3. The semiconductor light emitting device of claim 1, wherein the insulating part allows an upper region of the Zener diode part to be unexposed outwardly.

4. The semiconductor light emitting device of claim 1, wherein the first and second pad electrodes are not provided in a region of the Zener diode part.

5. The semiconductor light emitting device of claim 1, wherein the first and second pad electrodes occupy 80% to 95% of an area of an upper surface of the semiconductor light emitting device.

6. The semiconductor light emitting device of claim 1, wherein the LED part further includes at least one first electrode provided on one surface of the first conductivity type semiconductor layer, and
the first connection electrode is connected to the at least one first electrode.

7. The semiconductor light emitting device of claim 6, wherein the at least one first electrode penetrates the active layer and the second conductivity type semiconductor layer of the LED part, and
the at least one first electrode is enclosed by the insulating part and electrically separated from the active layer and the second conductivity type semiconductor layer.

8. The semiconductor light emitting device of claim 1, wherein the LED part further includes a second electrode provided on one surface of the second conductivity type semiconductor layer, and
the second connection electrode is connected to the second electrode.

9. The semiconductor light emitting device of claim 8, wherein the second electrode is formed of a light reflective material.

10. The semiconductor light emitting device of claim 8, wherein the second electrode is disposed to enclose the at least one first electrode.

11. The semiconductor light emitting device of claim 8, wherein the first and second electrodes have upper surfaces disposed on the same level.

12. The semiconductor light emitting device of claim 8, wherein the first and second electrodes are disposed in the same direction.

13. The semiconductor light emitting device of claim 1, wherein the first and second pad electrodes are formed of a eutectic metal.

14. A light emitting apparatus comprising:
a mounting substrate; and
a semiconductor light emitting device mounted on the mounting substrate and emitting light when an electrical signal is applied thereto,
wherein the semiconductor light emitting device includes:
a light emitting diode (LED) part disposed on one region of a light transmissive substrate and including a first conductivity type semiconductor layer, an active layer and a second conductivity type semiconductor layer;
a Zener diode part disposed on the other region of the light transmissive substrate and including a first conductivity type semiconductor layer, an active layer and a second conductivity type semiconductor layer;
a first connection electrode connecting the first conductivity type semiconductor layer of the LED part to the second conductivity type semiconductor layer of the Zener diode part;
a second connection electrode connecting the second conductivity type semiconductor layer of the LED part to the first conductivity type semiconductor layer of the Zener diode part;
an insulating part covering the first and second connection electrodes and having an open region allowing at least a portion of the first and second connection electrodes to be exposed; and
first and second pad electrodes formed on the first and second connection electrodes exposed through the open region and connected to the first and second connection electrodes, respectively.

15. The light emitting apparatus of claim 14, wherein the mounting substrate is a circuit board.

16. The light emitting apparatus of claim 14, wherein the mounting substrate is a lead frame.

17. The light emitting apparatus of claim 14, wherein the first and second pad electrodes are disposed toward the mounting substrate when the semiconductor light emitting device is mounted on the mounting substrate.
